(19) United States
(12) Patent Application Publication
(10) Pub. No.: US 2020/0340656 A1
(43) Pub. Date: Oct. 29, 2020

(54) DRIVING CIRCUIT BOX FOR DRIVING ILLUMINATING COMPONENT

(71) Applicant: XIAMEN ECO LIGHTING CO. LTD., Xiamen (CN)

(72) Inventors: Xiaojuan Huang, Xiamen (CN); Hao Luo, Xiamen (CN)

(21) Appl. No.: 16/398,180

(22) Filed: Apr. 29, 2019

(51) Int. Cl. F21V 23/00; H05K 5/03; H05K 5/02; H05K 5/04; H05K 5/00

(52) U.S. Cl. CPC F21V 23/008; F21V 23/006; H05K 5/0008; H05K 5/0247; H05K 5/04; H05K 5/03

(57) ABSTRACT

A driving circuit box includes a square-cylinder-shaped driving circuit component, a square-cylinder-shaped casing, a base plate, a lateral plate, a cover structure, a first cap and a second cap. The square-cylinder-shaped casing accommodates the square-cylinder-shaped driving circuit component via a first internal space. The first internal space fits the square-cylinder-shaped driving circuit component. The base plate extends along a first side of the square-cylinder-shaped casing. The lateral plate extends from the base plate orthogonally to the first side. The cover structure includes a first cover plate and a second cover plate. The cover structure, the base plate, and the lateral plate form a second internal space. The second internal space is substantially separated from the first internal space by the first lateral side of the square-cylinder-shaped casing.

### BACKGROUND OF THE INVENTION

### 1. Field of the Invention

The present invention relates to a driving circuit box for driving an illuminating component, and more particularly, to a driving circuit box that efficiently facilitates installing conductive lines.

### 2. Description of the Prior Art

A conventional driving circuit box can be specifically designed to drive an external illuminating component. Such conventional driving circuit box is usually square-cylinder-shaped for accommodating a driving circuit board within using an inner single space. And the driving circuit needs to electrically couple to a conductive wire for receiving an external power. The conductive wire is also deposited within the conventional driving circuit box's inner single space for aiding in installation of the conventional driving circuit box.

However, such single space may introduce one primary defect. For example, after an engineer installs the conventional driving circuit box, he or she may have trouble in folding the conductive wire into the inner single space. Worse of it, the conductive wire may be exposed to outside of the conventional driving circuit box if the engineer cannot fix the conductive wire's folding problem. Moreover, the exposed conductive wire may leave a breach for dust to stack within the single inner space. If the stacked dusts are not timely taken care of, power failure or malfunctioning may easily occur to the conventional driving circuit box.

### SUMMARY OF THE INVENTION

The present invention aims at disclosing a driving circuit box for driving an illuminating component. Moreover, the disclosed driving circuit box is capable of substantially preventing the conductive wire from disturbing an engineer's installation of the driving circuit board. Other defects caused by an exposed conductive wire can thereby be significantly neutralized.

According to one embodiment of the present invention, the driving circuit box includes a square-cylinder-shaped driving circuit component, a square-cylinder-shaped casing, a base plate, a lateral plate, a cover structure, a first cap and a second cap. The square-cylinder-shaped driving circuit component is electrically coupled to an illuminating component. Also, the square-cylinder-shaped driving circuit component drives the illuminating component. The square-cylinder-shaped casing accommodates the square-cylinder-shaped driving circuit component via a first internal space of the square-cylinder-shaped casing. The first internal space fits the square-cylinder-shaped driving circuit component. The base plate extends along a first side of the square-cylinder-shaped casing. The lateral plate extends from the base plate orthogonally to the first side of the square-cylinder-shaped casing. The cover structure includes a first cover plate and a second cover plate. The first cover plate is detachably engaged with the lateral plate. The first cover plate is orthogonal to the first side of the square-cylinder-shaped casing. The second cover plate is orthogonal to the first cover plate and parallel to the base plate. The first cover plate and the second cover plate are integrally affixed to each other. The cover structure, the base plate, and the lateral plate form a second internal space. The second internal space is substantially separated from the first internal space by the first lateral side of the square-cylinder-shaped casing. The first cap substantially blocks both a first side of the first internal space and a first side of the second internal space. The second cap substantially blocks both a second side of the first internal space and a second side of the second internal space. The second side of the first internal space is opposite to the first side of the first internal space. And the second side of the second internal space is opposite to the first side of the second internal space.

In one example, the square-cylinder-shaped casing, the base plate, and the lateral plate form an integral structure.

In one example, the square-cylinder-shaped casing further includes a through hole on the first lateral side of the square-cylinder-shaped casing. The second internal space further places an output conductive wire. And the through hole allows the output conductive wire to pass through for electrically connecting to the square-cylinder-shaped driving circuit component.

In one example, the first cap further includes a through hole that faces the first internal space. The square-cylinder-shaped driving circuit component further includes a power wire. The through hole allows the external power wire to pass through.

In one example, the power line further includes a line stopper. The line stopper stops a relative movement of the power line towards the first cap while the line stopper is pushed against the through hole. And the line stopper has a larger area than that of the through hole.

In one example, the first cap further includes a rapping hole that faces the second internal space. The rapping hole allows installation of an output conductive wire within the second internal space.

In one example, the second cap further includes a rapping hole that faces the second internal space. The rapping hole allows installation of an output conductive wire within the second internal space.

In one example, the square-cylinder-shaped driving circuit component includes a driving circuit board and a metal housing. The metal housing accommodates the driving circuit board. The metal housing is coated with an insulation layer that isolates the driving circuit board from the metal housing. In one example, the square-cylinder-shaped casing further includes a first hook. And the first cover plate further comprises a second hook. The first hook and the second hook detachably engage with each other. Such that the square-cylinder-shaped casing detachably engages with the first cover plate.

In one example, the first plate further includes a stopper. The stopper stops a relative movement of the first plate towards the square-cylinder-shaped casing while the first plate is pushed against the square-cylinder-shaped casing. In one example, the first hook and the second hook further form a gap in between.

In one example, the lateral plate further includes a hook, and the second cover plate further includes a stopper. The hook and the stopper detachably engage with each other while the second plate is pushed against the lateral plate. Such that the lateral plate detachably engages with the second cover plate. In one example, the hook and the stopper further form a gap in between. In one example, the square-cylinder-shaped casing further includes at least one screw receiving hole. The first cap further includes at least one through hole that respectively correspond to the at least one screw receiving hole. The driving circuit box further includes at least one screw. The at least one screw screws into the at least one screw receiving hole via the at least one through hole. Such that the at least one screw screws the first cap onto the square-cylinder-shaped casing.

In one example, the base plate further includes at least one screw receiving hole. The first cap further includes at least one through hole that respectively correspond to the at least one screw receiving hole. The driving circuit box further includes at least one screw. The at least one screw screws into the at least one screw receiving hole via the at least one through hole. Such that the at least one screw screws the first cap onto the base plate.

In one example, the lateral plate further includes at least one screw receiving hole. The first cap further includes at least one through hole that respectively correspond to the at least one screw receiving hole. The driving circuit box further includes at least one screw. The at least one screw screws into the at least one screw receiving hole via the at least one through hole. Such that the at least one screw screws the first cap onto the lateral plate.

In one example, the square-cylinder-shaped casing further includes at least one screw receiving hole. The second cap further includes at least one through hole that respectively correspond to the at least one screw receiving hole. The driving circuit box further includes at least one screw. The at least one screw screws into the at least one screw receiving hole via the at least one through hole. Such that the at least one screw screws the second cap onto the square-cylinder-shaped casing.

In one example, the base plate further includes at least one screw receiving hole. The second cap further includes at least one through hole that respectively correspond to the at least one screw receiving hole. The driving circuit box further includes at least one screw. The at least one screw screws into the at least one screw receiving hole via the at least one through hole. Such that the at least one screw screws the second cap onto the base plate.

In one example, the lateral plate further includes at least one screw receiving hole. The second cap further includes at least one through hole that respectively correspond to the at least one screw receiving hole. The driving circuit box further includes at least one screw. The at least one screw screws into the at least one screw receiving hole via the at least one through hole. Such that the at least one screw screws the second cap onto the lateral plate.

In one example, the first cover plate further detachably engages with the square-cylinder-shaped casing via a snap fit, a threaded fit, an interference fit, a tongue-and-groove fit, a post-and-bore fit, or a press fit.

In one example, the second cover plate further detachably engages with the lateral plate via a snap fit, a threaded fit, an interference fit, a tongue-and-groove fit, a post-and-bore fit, or a press fit.

In one example, the first cap further detachably engages with at least one of the square-cylinder-shaped casing, the base plate, and the lateral plate via a snap fit, a threaded fit, an interference fit, a tongue-and-groove fit, a post-and-bore fit, or a press fit.

In one example, the second cap further detachably engages with at least one of the square-cylinder-shaped casing, the base plate, and the lateral plate via a snap fit, a threaded fit, an interference fit, a tongue-and-groove fit, a post-and-bore fit, or a press fit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a split diagram of the driving circuit box according to one embodiment of the present invention.

FIG. 2 illustrates a stereogram of the split diagram of the driving circuit box shown in FIG. 1.

FIG. 3 illustrates a lateral view of the driving circuit box shown in FIG. 1.

FIG. 4 illustrates a lateral perspective view of the driving circuit box shown in FIG. 1.

### DETAILED DESCRIPTION

As mentioned above, the present invention discloses a driving circuit box for driving an illuminating component. The disclosed driving circuit box is capable of effectively neutralizing defects caused in the conventional driving circuit box.

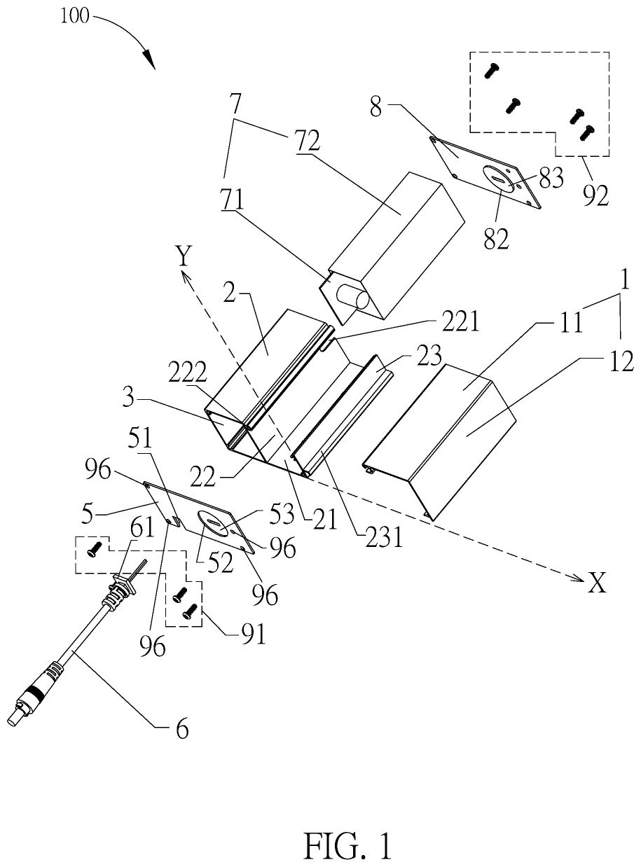

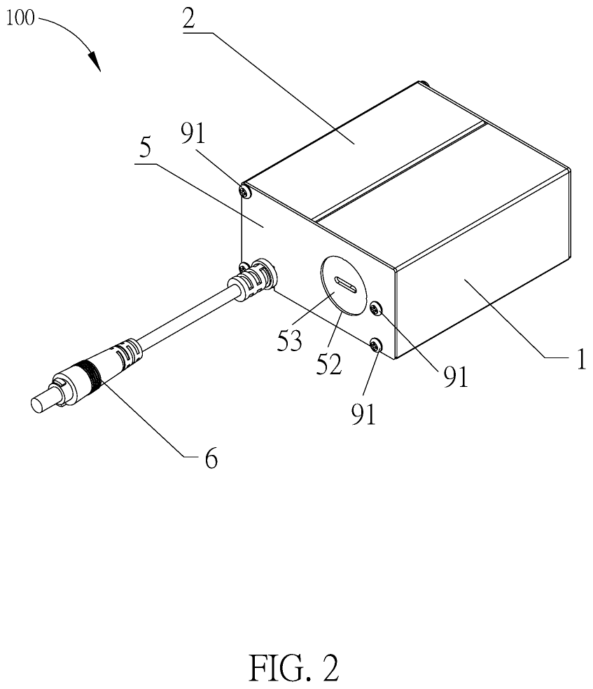

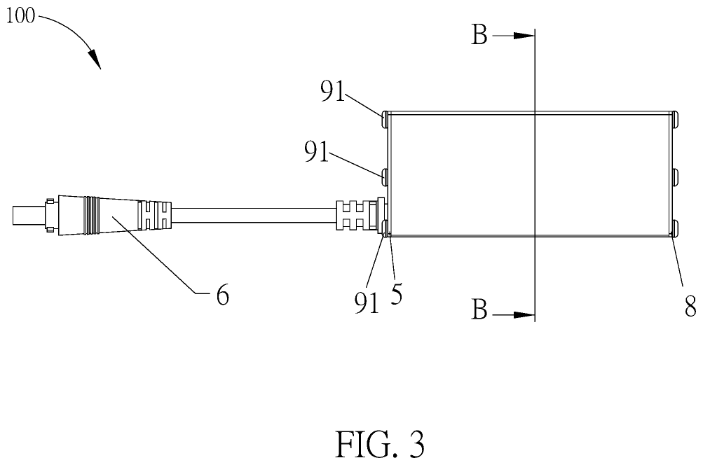

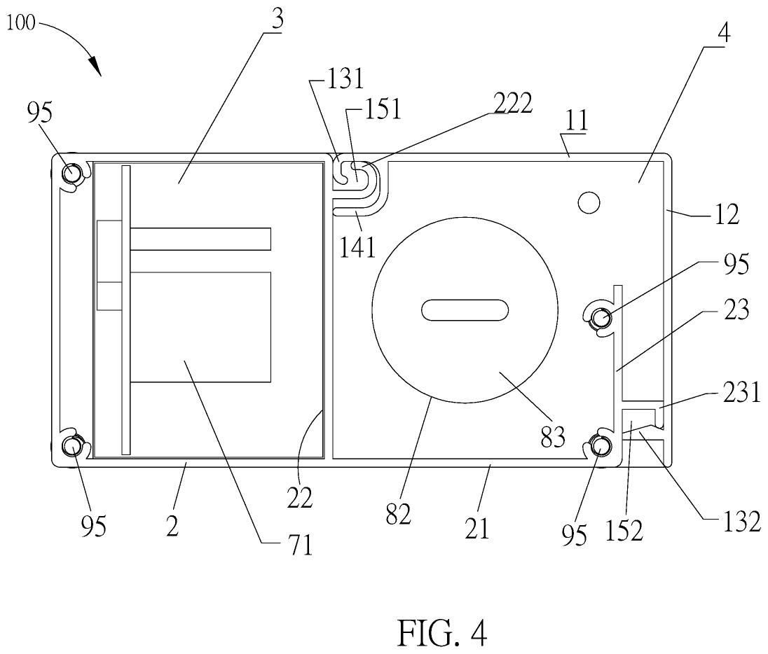

FIGS. 1-4 illustrate a driving circuit box 100 for driving an illuminating component (not shown) according to one embodiment of the present invention. More specifically, FIG. 1 illustrates a split diagram of the driving circuit box 100 according to one example. FIG. 2 illustrates a stereogram of the split diagram of the driving circuit box 100 according to one example. FIG. 3 illustrates a lateral view of the driving circuit box 100 according to one example. FIG. 4 illustrates a lateral perspective view of the driving circuit box 100 according to one example.

According to one example, the driving circuit box 100 includes a square-cylinder-shaped driving circuit component 7, a square-cylinder-shaped casing 2, a base plate 21, a lateral plate 23, a cover structure 1, and caps 5 and 8.

The square-cylinder-shaped driving circuit component 7 is specifically designed for driving an illuminating component. More particularly, the square-cylinder-shaped driving circuit component 7 is electrically coupled to an illuminating component. Also, the square-cylinder-shaped driving circuit component 7 drives the illuminating component via the electrical connection in between.

The square-cylinder-shaped casing 2 is designed for substantially protecting the square-cylinder-shaped driving circuit component 7 by fitting an external shape of the square-cylinder-shaped casing 2. More particularly, the square-cylinder-shaped casing 2 accommodates the square-cylinder-shaped driving circuit component 7 via a first internal space 3 enclosed within. Also, the square-cylinder-shaped casing 2 fits the square-cylinder-shaped driving circuit component 7's external shape via the first internal space 3.

The base plate 21 extends along a first side of the square-cylinder-shaped casing 2, as depicted by the orientation X shown in FIG. 1. The lateral plate 23 extends from the base plate 21 substantially orthogonally to the first side of the square-cylinder-shaped casing 2, i.e., along another orientation Y orthogonal to the orientation X shown in FIG. 1.

The cover structure 1 includes a first cover plate 12 and a second cover plate 11. The cover plate 12 detachably engages with the lateral plate 23. Also, the cover plate 12 extends along the orientation Y, i.e., orthogonally to the first side of the square-cylinder-shaped casing 2. The cover plate 11 is orthogonal to the cover plate 12. In addition, the cover plate 11 is parallel to the base plate 21 along the orientation X. In some example, the cover plates 11 and 12 are integrally affixed to each other for better structural strength of the cover structure 1.

In some examples, the cover structure 1, the base plate 21, and the lateral plate 23 form a second internal space 4, as shown in FIG. 4. The second internal space 4 is substantially separated from the first internal space 3 by a first lateral side of the square-cylinder-shaped casing 2, e.g., a sidewall 22 as depicted in FIG. 1 and FIG. 4.

The caps 5 and 8 are designed for substantially sealing both sides of the driving circuit box 100. Specifically, the caps 5 and 8 are designed for substantially sealing openings of the internal spaces 3 and 4. In some examples, the caps 5 and 8 share substantially a same structure. However, tiny differences between the caps 5 and 8 are allowed for customized design purposes.

In one example, one of the caps 5 and 8 substantially blocks both a first side of the first internal space 3 and a first side of the second internal space 4. Also, the other cap substantially blocks both a second side of the first internal space 3 and a second side of the second internal space 4. It is noted that the second side of the first internal space 3 is opposite to the first side of the first internal space 3. And the second side of the second internal space 4 is opposite to the first side of the second internal space 4.

The driving circuit box 100 has a primary advantage in segmenting the first inner space 3 and the second inner space.

Since the first inner space 3 is dedicated to accommodate the square-cylinder-shaped driving circuit component 7, the second inner space 4 can be used to accommodate other required elements of the driving circuit box 100. In this way, the square-cylinder-shaped driving circuit component 7's operations can be substantially immune from being disturbed, no matter from outside the driving circuit box 100 or anything accommodated by the second inner space 4.

In one example, the square-cylinder-shaped casing 2, the base plate 21, and the lateral plate 23 form an integral structure. Such that the driving circuit box 100's structural strength is improved.

In some examples, the square-cylinder-shaped casing 2 further includes a through hole 221 on its first lateral side, specifically, on the sidewall 25 that is disposed between the first inner space 3 and the second inner space 4. In some examples, the second inner space 4 is used for placing an output conductive wire (not shown) that electrically connects to the square-cylinder-shaped driving circuit component 7. And the through hole 221 allows the output conductive wire to pass for forming the abovementioned electrical connection. In this way, the output conductive wire can be easily installed without interfering the square-cylinder-shaped driving circuit component 7 while someone intends to install the driving circuit box 100.

As mentioned above, the caps 5 and 8 may have certain customized difference. In one example, the cap 5 includes a through hole 51 that faces the first internal space 3, whereas the cap 8 may not have such through hole. In addition, the square-cylinder-shaped driving circuit component 7 may further includes a power wire 6. And the through hole 51 allows the power wire 6 to pass through. However, in some other examples, the cap 8 may also have a through hole for the power wire 6 whereas the cap 5 does not have it. That is, it depends on a customized choice to decide which cap among the caps 5 and 8 to have the through hole for allowing the power wire 6 to pass through. Also, in some examples, the power line 6 further includes a line stopper 61. The line stopper 61 stops a relative movement of the power line 6 towards the cap 5 while the line stopper 61 is pushed against the through hole 51. The line stopper 61's stopping force works better when the line stopper 61 has a larger area than that of the through hole 51. It is noted that the line stopper 61 is disposed within the first inner space 3 while the power line 6 is electrically connected to the square-cylinder-shaped driving circuit component 7. In this way, when anyone intends to pull the power line 6 out of the first inner space 3, no matter erroneously or maliciously, the line stopper 61 can effectively stop such pull force and substantially protect the power line 6 from being damaged by the pull force.

In some examples, either one of the caps 5 and 8 further includes a rapping hole, e.g., a rapping hole 52 disposed on the cap 5 or a rapping hole 82 disposed on the cap 8. Also, either one of the rapping holes 52 and 82 may include a respective rapping plate, e.g., a rapping plate 53 that detachably blocks the rapping hole 52 or a rapping plate 83 that detachably blocks the rapping hole 82. In addition, the rapping hole 52 or 82 faces the second inner space 4. In this way, either one the rapping plate 53 and 83 can substantially protect the second inner space 4 from being breached by undesired substance, such as external dust or dirt, before the driving circuit box 100 is installed. Also, when the driving circuit box 100 is installed, at least one of the rapping plates 53 and 83 can be removed, such that the corresponding rapping hole 52 or 82 can allow the output conductive wire to pass and be deposited inside the second inner space 4 for completing installation of the output conductive wire.

In some examples, the square-cylinder-shaped driving circuit component 7 includes a driving circuit board 71 and a metal housing 72. The metal housing 72 accommodates and thus protects the driving circuit board 71. The metal housing 72 is additional coated with an insulation layer, inside or outside, such that the insulation layer can isolate the driving circuit board 71 from the metal housing 72 to substantially avoid electric interference.

In some examples, the present invention discloses a few specific structures to better engage the cover structure 1 with the square-cylinder-shaped casing 7 and the lateral plate 23. In this way, the driving circuit box 100's structural strength is enhanced.

In one example, as illustrated in FIG. 4, the square-cylinder-shaped casing 7 further includes a hook 222. Also, the cover plate 11 further includes a hook 131. With the aid of a predetermined design, the hooks 222 and 131 are capable of detachably engaging with each other. Such that the square-cylinder-shaped casing 2 detachably engages with the cover plate 11. In another example, the cover plate 11 further includes a stopper 141. The stopper 141 stops a relative movement of the cover plate 11 towards the square-cylinder-shaped casing 2 while the cover plate 11 is pushed against the square-cylinder-shaped casing 2 for assembling purposes. In still another example, the hooks 222 and 131 form a gap 151 in between for foolproof purposes, in case that a user mistakenly damages the hooks 222 and 131 during the assembling process.

In one example, the lateral plate 23 has a hook 231, and the cover plate 12 has a stopper 132. With the aid of a predetermined design, the hook 231 and the stopper 132 detachably engage with each other while the cover plate 12 is pushed against the lateral plate 23. Such that the lateral plate 23 detachably engages with the cover plate 12. Similarly, in another example, the hook 231 and the stopper 132 form a gap 152 in between for foolproof purposes, in case that a user mistakenly damages the hook 231 and the stopper 132 during the assembling process.

In some examples, screws are additionally used for better affixing the caps 5 and 8 to the square-cylinder-shaped casing 2, the base plate 21, and/or the lateral plate 23.

In one example, the square-cylinder-shaped casing 2, the base plate 21, and/or the lateral plate 23 further include at least one screw receiving hole 95. Moreover, the cap 5 or 8 further includes at least one through hole, e.g. at least one through hole 96 disposed on the cap 5, which is respectively correspond to the at least one screw receiving hole 95. In addition, the driving circuit box 100 further includes at least one screw 91. The at least one screw 91 screws into the at least one screw receiving hole 95 via the at least one through hole 96. Such that the at least one screw 91 screws the cap 5 or 8 onto the square-cylinder-shaped casing 2, the base plate 21, and/or the lateral plate 23. In some examples, it is noted that the amount and/or the locations of the at least one screw 91, the at least one screw receiving hole 95, and/or the at least one through hole 96 is optional, as long as each screw has a corresponding receiving hole and a corresponding through hole to fix. That is, the square-cylinder-shaped casing 2, the base plate 21, and/or the lateral plate 23 may optionally include the above-mentioned elements for screwing the at least one screw 91.

In some examples, the cover plate 11 may be detachably engage with the square-cylinder-shaped casing 2 via a snap fit, a threaded fit, an interference fit, a tongue-and-groove fit, a post-and-bore fit, or a press fit.

In some examples, the cover plate 12 may detachably engage with the lateral plate via a snap fit, a threaded fit, an interference fit, a tongue-and-groove fit, a post-and-bore fit, or a press fit.

In some examples, the cap 5 or 8 may detachably engage with at least one of the square-cylinder-shaped casing 2, the base plate 21, and the lateral plate 23 via a snap fit, a threaded fit, an interference fit, a tongue-and-groove fit, a post-and-bore fit, or a press fit.

Those skilled in the art will readily observe that numerous modifications and alterations of the device and method may be made while retaining the teachings of the invention. Accordingly, the above disclosure should be construed as limited only by the metes and bounds of the appended claims.

1. A driving circuit box for driving an illuminating component, comprising:
a square-cylinder-shaped driving circuit component, which is electrically coupled to and configured to drive an illuminating component;
a square-cylinder-shaped casing, configured to accommodate the square-cylinder-shaped driving circuit component via a first internal space of the square-cylinder-shaped casing that fits the square-cylinder-shaped driving circuit component;
a base plate, which extends along a first side of the square-cylinder-shaped casing;
a lateral plate, which extends from the base plate orthogonally to the first side of the square-cylinder-shaped casing;
a cover structure, comprising:
a first cover plate, configured to detachably engaged with the lateral plate, wherein the first cover plate is orthogonal to the first side of the square-cylinder-shaped casing; and
a second cover plate, orthogonal to the first cover plate and parallel to the base plate, wherein the first cover plate and the second cover plate are integrally affixed to each other;
wherein the cover structure, the base plate, and the lateral plate form a second internal space, which is substantially separated from the first internal space by the first lateral side of the square-cylinder-shaped casing;
a first cap, configured to substantially block both a first side of the first internal space and a first side of the second internal space; and
a second cap, configured to substantially block both a second side of the first internal space and a second side of the second internal space, wherein the second side of the first internal space is opposite to the first side of the first internal space, and the second side of the second internal space is opposite to the first side of the second internal space, wherein the square-cylinder-shaped driving circuit component comprises a driving circuit board and a metal housing, configured to accommodate the driving circuit board, wherein the metal housing is coated with an insulation layer that isolates the driving circuit board from the metal housing.

2. The driving circuit box of claim 1, wherein the square-cylinder-shaped casing, the base plate, and the lateral plate form an integral structure.

3. The driving circuit box of claim 1, wherein the square-cylinder-shaped casing further comprises a through hole on the first lateral side of the square-cylinder-shaped casing; and
wherein the second internal space is further configured to place an output conductive wire, and the through hole is configured to allow the output conductive wire to pass through for electrically connecting to the square-cylinder-shaped driving circuit component.

4. The driving circuit box of claim 1, wherein the first cap further comprises a through hole that faces the first internal space;
wherein the square-cylinder-shaped driving circuit component further comprises a power wire; and
wherein the through hole is configured to allow the power wire to pass through.

5. The driving circuit box of claim 4, wherein the power wire further comprising a line stopper, which is configured to stop a relative movement of the power line towards the first cap while the line stopper is pushed against the through hole, wherein the line stopper has a larger area than that of the through hole.

6. The driving circuit box of claim 1, wherein the first cap further comprising a rapping hole that faces the second internal space;
wherein the rapping hole is configured to allow installation of an output conductive wire within the second internal space.

7. The driving circuit box of claim 1, wherein the second cap further comprising a rapping hole that faces the second internal space;
wherein the rapping hole is configured to allow installation of an output conductive wire within the second internal space.

8. (canceled)

9. The driving circuit box of claim 1, wherein the square-cylinder-shaped casing further comprises a first hook, and the first cover plate further comprises a second hook;
wherein the first hook and the second hook are configured to detachably engage with each other, such that the square-cylinder-shaped casing detachably engages with the first cover plate.

10. The driving circuit box of claim 9, wherein the first cover plate further comprises a stopper, which is configured to stop a relative movement of the first cover plate towards the square-cylinder-shaped casing while the first cover plate is pushed against the square-cylinder-shaped casing.

11. The driving circuit box of claim 9, wherein the first hook and the second hook are further configured to form a gap in between.

12. The driving circuit box of claim 1, wherein the lateral plate further comprises a hook, and the second cover plate further comprises a stopper;
wherein the hook and the stopper are configured to detachably engage with each other while the second cover plate is pushed against the lateral plate, such that the lateral plate detachably engages with the second cover plate.

13. The driving circuit box of claim 12, wherein the hook and the stopper are further configured to form a gap in between.

14. The driving circuit box of claim 1, wherein the square-cylinder-shaped casing further comprises at least one screw receiving hole;
wherein the first cap further comprises at least one through hole that respectively correspond to the at least one screw receiving hole; and
wherein the driving circuit box further comprises at least one screw, which is configured to screw into the at least one screw receiving hole via the at least one through hole, such that the at least one screw screws the first cap onto the square-cylinder-shaped casing.

15. The driving circuit box of claim 1, wherein the base plate further comprises at least one screw receiving hole;
wherein the first cap further comprises at least one through hole that respectively correspond to the at least one screw receiving hole; and
wherein the driving circuit box further comprises at least one screw, which is configured to screw into the at least one screw receiving hole via the at least one through hole, such that the at least one screw screws the first cap onto the base plate.

16. The driving circuit box of claim 1, wherein the lateral plate further comprises at least one screw receiving hole;
wherein the first cap further comprises at least one through hole that respectively correspond to the at least one screw receiving hole; and
wherein the driving circuit box further comprises at least one screw, which is configured to screw into the at least one screw receiving hole via the at least one through hole, such that the at least one screw screws the first cap onto the lateral plate.

17. The driving circuit box of claim 1, wherein the square-cylinder-shaped casing further comprises at least one screw receiving hole;
wherein the second cap further comprises at least one through hole that respectively correspond to the at least one screw receiving hole; and
wherein the driving circuit box further comprises at least one screw, which is configured to screw into the at least one screw receiving hole via the at least one through hole, such that the at least one screw screws the second cap onto the square-cylinder-shaped casing.

18. The driving circuit box of claim 1, wherein the base plate further comprises at least one screw receiving hole;
wherein the second cap further comprises at least one through hole that respectively correspond to the at least one screw receiving hole; and
wherein the driving circuit box further comprises at least one screw, which is configured to screw into the at least one screw receiving hole via the at least one through hole, such that the at least one screw screws the second cap onto the base plate.

19. The driving circuit box of claim 1, wherein the lateral plate further comprises at least one screw receiving hole;
wherein the second cap further comprises at least one through hole that respectively correspond to the at least one screw receiving hole; and
wherein the driving circuit box further comprises at least one screw, which is configured to screw into the at least one screw receiving hole via the at least one through hole, such that the at least one screw screws the second cap onto the lateral plate.

20. The driving circuit box of claim 1, wherein the first cover plate is further configured to detachably engage with the square-cylinder-shaped casing via a snap fit, a threaded fit, an interference fit, a tongue-and-groove fit, a post-and-bore fit, or a press fit.

21. The driving circuit box of claim 1, wherein the second cover plate is further configured to detachably engage with the lateral plate via a snap fit, a threaded fit, an interference fit, a tongue-and-groove fit, a post-and-bore fit, or a press fit.

22. The driving circuit box of claim 1, wherein the first cap is further configured to detachably engage with at least one of the square-cylinder-shaped casing, the base plate, and the lateral plate via a snap fit, a threaded fit, an interference fit, a tongue-and-groove fit, a post-and-bore fit, or a press fit.

23. The driving circuit box of claim 1, wherein the second cap is further configured to detachably engage with at least one of the square-cylinder-shaped casing, the base plate, and the lateral plate via a snap fit, a threaded fit, an interference fit, a tongue-and-groove fit, a post-and-bore fit, or a press fit.
